(19) United States
(12) Patent Application Publication
(10) Pub. No.: US 2010/0127380 A1
(43) Pub. Date: May 27, 2010

(54) LEADFRAME FREE LEADLESS ARRAY SEMICONDUCTOR PACKAGES

(76) Inventors: Manolito Galera, Singapore (PH); Leocadio Morona Alabin, Singapore (PH)

Correspondence Address: KENNETH E. HORTON;KIRTON & MCCONKLE, 60 EAST SOUTH TEMPLE, SUITE 1800, SALTLAKE CITY, UT, 84111, US

(21) Appl. No.: 12/323,895

(22) Filed: Nov. 26, 2008

(51) Int. Cl. H01L 23/498; H01L 21/98

(52) U.S. Cl. 257/692; 438/127; 257/E23.069; 257/E21.705

(57) ABSTRACT

Leadframe-free semiconductor packages and methods for making and using the same are described. The semiconductor packages contain an interconnect structure comprising an array of land pads. The interconnect structure is formed from and routed using a printable or wirebondable conductive material and is not formed using any etching procedure. A solderable mask covers the interconnect structure except for the land pads. A die containing an integrated circuit device is connected to the interconnect structure by either a wirebonding process or by a flipchip process. The land pad arrays can contain a solder connector, such as a solder ball or bump, that can be used to connect the semiconductor package to a printed circuit board. Other embodiments are described.

### FIELD

This application relates generally to semiconductor devices and methods for making such devices. More specifically, this application describes leadframe-free semiconductor packages and methods for making and using such packages.

### BACKGROUND

Semiconductor packages are well known in the art. Often, these packages may include one or more semiconductor devices, such as an integrated circuit (“IC”) die or chip, which may be connected to a die pad that is centrally formed in a lead frame which contain a series of leads. In some cases, bond wires electrically connect the IC die to a series of terminals that serve as an electrical connection to an external device, such as a printed circuit board (“PCB”). An encapsulating material can be used to cover the bond wires, the IC die, the terminals, and/or other components of the semiconductor device to form the exterior of the semiconductor package. A portion of the terminals and possibly a portion of the die pad may be externally exposed from the encapsulating material. In this manner, the die may be protected from environmental hazards—such as moisture, contaminants, corrosion, and mechanical shock—while being electrically and mechanically connected to an intended device that is external to the semiconductor package.

After it has been formed, the semiconductor package is often used in an ever growing variety of electronic applications, such as disk drives, USB controllers, portable computer devices, cellular phones, and so forth. Depending on the die and the electronic application, the semiconductor package may be highly miniaturized and may need to be as small as possible.

### SUMMARY

This application relates to leadframe-free semiconductor packages and methods for making and using the same. The semiconductor packages contain an interconnect structure comprising an array of land pads. The interconnect structure is formed from and routed using a printable or wirebondable conductive material and is not formed using any etching procedure. A solderable mask covers the interconnect structure except for the land pads. A die containing an integrated circuit device is connected to the interconnect structure by either a wirebonding process or by a flipchip process. The land pad arrays can contain a solder connector, such as a solder ball or bump, that can be used to connect the semiconductor package to a printed circuit board.

### BRIEF DESCRIPTION OF THE DRAWINGS

The following description can be better understood in light of the Figures, in which:

FIG. 1 shows some embodiments of a method for making semiconductor packages where a tape has been formed on a carrier frame;

FIGS. 2a and b depict some embodiments of a method for making semiconductor packages where an interconnect structure has been formed;

FIG. 3 shows some embodiments of a method for making semiconductor packages where a die has been attached to the interconnect structure;

FIG. 4 depicts some embodiments of a method for making semiconductor packages showing wirebonds connecting the die to the interconnect structure;

FIG. 5 shows some embodiments of a method for making semiconductor packages showing a die that has been attached to the interconnect structure;

FIG. 6 shows some embodiments of a method for making semiconductor packages showing a molding step;

FIG. 7 depicts some embodiments of a method for making semiconductor packages where the carrier frame and tape have been removed;

FIG. 8 shows some embodiments of a method for making semiconductor packages where a solder mask has been formed;

FIGS. 9-10 depict some embodiments of a method for making semiconductor packages showing the formation of solder connectors;

FIGS. 11-12 depicts top views of some embodiments of a method for making semiconductor packages after a singulation process has been performed;

FIGS. 13-14 depicts side views of some embodiments of semiconductor packages after a singulation process has been performed; and

FIGS. 15-16 depicts side views of some embodiments of semiconductor packages after a singulation process has been performed.

The Figures illustrate specific aspects of the semiconductor packages and methods for making such packages. Together with the following description, the Figures demonstrate and explain the principles of the methods and structures produced through these methods. In the drawings, the thickness of layers and regions are exaggerated for clarity. It will also be understood that when a layer, component, or substrate is referred to as being “on” another layer, component, or substrate, it can be directly on the other layer, component, or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the semiconductor packages and associated methods of making and using the packages can be implemented and used without employing these specific details. Indeed, the semiconductor packages and associated methods can be placed into practice by modifying the illustrated devices and methods and can be used in conjunction with any other apparatus and techniques conventionally used in the industry. For example, while the description below focuses on methods for making semiconductor packages in the IC industry, it could be used in packaging for other electronic devices like optoelectronic devices, solar cells, MEMS structures, lighting controls, power supplies, and amplifiers.

Some embodiments of the semiconductor packages and methods for making such packages are shown in the Figures. In these embodiments, the methods for making the semiconductor packages begin by providing a carrier frame (or frame) 10, as shown in FIG. 1. The carrier frame 10 can be any frame that is low-cost, reusable and can support the process requirements described herein, as well as any frame that can re-used as a substrate for tape 15. The carrier frame 10 can be manufactured by any known process, such as a stamping, or etching process.

The carrier frame 10 can have any size and thickness that is needed to operate as a support substrate during the manufacturing process and yet be re-usable. Thus, the size and thickness of the carrier frame 10 will depend on the size and density of the semiconductor package, as well as the semiconductor die (or dies) that will be contained in semiconductor package. The carrier frame 10 can comprise any metal or metal alloy known in the art, including Cu, steel alloy, or combinations thereof. In some embodiments, the frame 10 comprises Cu or steel alloy. In other embodiments, the carrier frame can comprise non-metal materials that can withstand molding temperature and have the required physical strength to support the components of the semiconductor package during assembly process until the frame 10 is removed. In some embodiments, the lead frame is substantially rectangular with a size ranging from about 9,000 to about 20,000 mm² and a thickness ranging from about 0.15 to about 0.5 mm.

As shown in FIG. 1, a tape 15 can then be provided on the carrier frame 10. The tape 15 is supported by the carrier frame 10 and so can be made of a flexible or a semi-flexible material. As well, once the semiconductor package is formed, the tape (and the carrier frame) can be removed. So the tape can be made of any material that is partially adhesive, but can be removed when molding process is complete or when it is peeled off. Any material having these characteristics can be used, including polyimide, silicone-free tape, or other thin-film materials. While the width and length of the tape 15 can be substantially similar to that of the carrier frame 10, the thickness of the tape 15 can range from about 0.008 mm to about 0.05 mm.

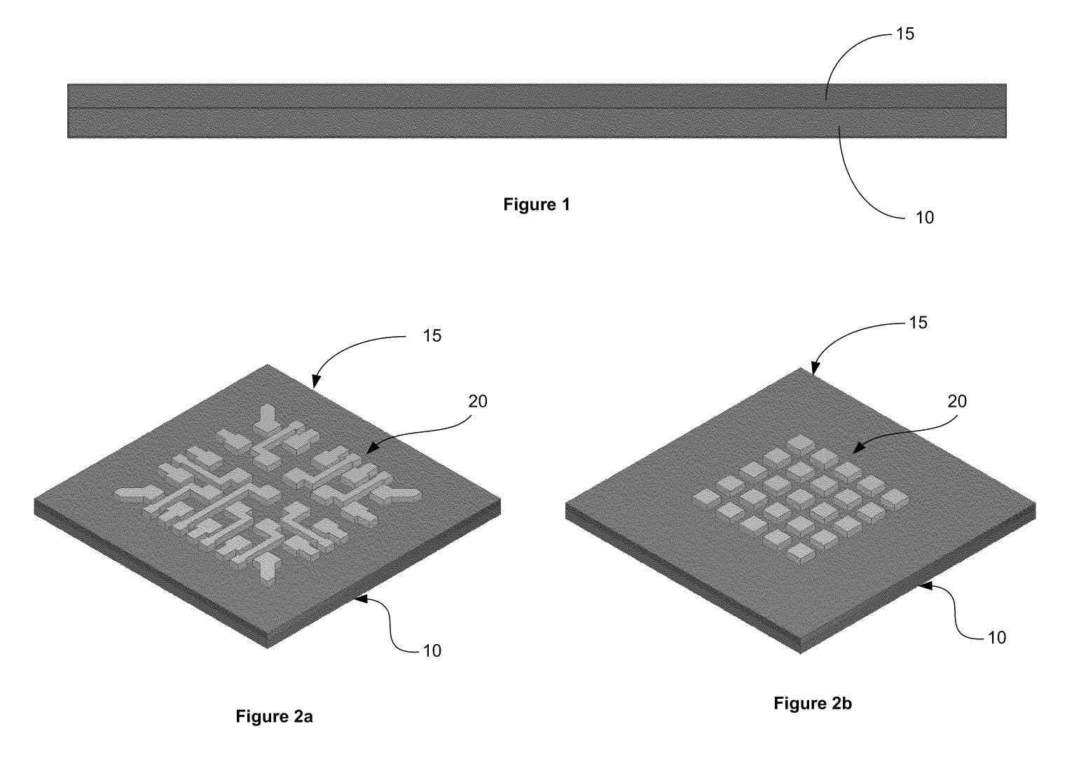

As shown in FIG. 2, an interconnect structure 20 can then be provided on the tape 15. The interconnect structure 20 serves to electrically connect a die containing an IC device with an external device (i.e., a printed circuit board) in the completed semiconductor package. As well, when the carrier frame 10 and tape 15 are removed, the interconnect structure will also serve as the land pad array for the semiconductor package. Thus, the interconnect structure 20 can have any pattern that serves both as an interconnect and as a land pad array for the semiconductor packages.

In some embodiments, the pattern of the interconnect structure 20 is depicted in FIG. 2a. In these embodiments, the interior portion of the pattern ends with those parts that will operate as land pads. The exterior portion of the pattern ends with those parts that will be connected to wirebonds. In other embodiments, the pattern of the interconnect structure can be configured as shown in FIG. 2b.

The interconnect structure 20 can be made of any conductive material that can also serve as a land pad. In some embodiments, such as those depicted in FIG. 2a, the interconnect structure can comprise any solderable and wire-bondable material, such as Au, Ag, Pd—Ag, Pt—Ag or combinations thereof. In other embodiments, such as those depicted in FIG. 2b, the interconnect structure can comprise any solderable and wire-bondable conductive material, such as Au, Ag, Pd—Ag, Pt—Ag, or combinations thereof.

The interconnect structure 20 can be formed by any process that will provide the desired pattern on the tape 15. In some embodiments, the interconnect structure 20 can be formed by using any known deposition process, and known masking and etching process. In other embodiments, the interconnect structure 20 can be made by any dispensing or screen printing process known in the art, such as by using a mesh stainless steel screen and then allowing the wet prints to level for 5 to 10 minutes before drying using a convection oven or belt dryer for 10 to 15 minutes.

Next, a semiconductor die 25 (or die) containing an IC device is disposed on the interconnect structure 20. The die 25 may be made of any suitable semiconductor material. Some non-limiting examples of such materials may include silicon, polysilicon, gallium arsenide, silicon carbide, gallium nitride, silicon and germanium, and combinations thereof.

The die 25 can contain any number of IC devices. The IC device may be any known integrated circuit in the art. Some non-limiting examples of these devices may include logic or digital IC device, linear regulators, audio power amplifiers, LDO, driver IC, or any combinations of these devices.

In those embodiments where wirebonding will be used, the semiconductor die 25 containing the IC device(s) will be attached to the interconnect structure by using any known pick & place process. After being attached, the exterior portions of the interconnect structure 20 remain exposed and are not covered by the die 25.

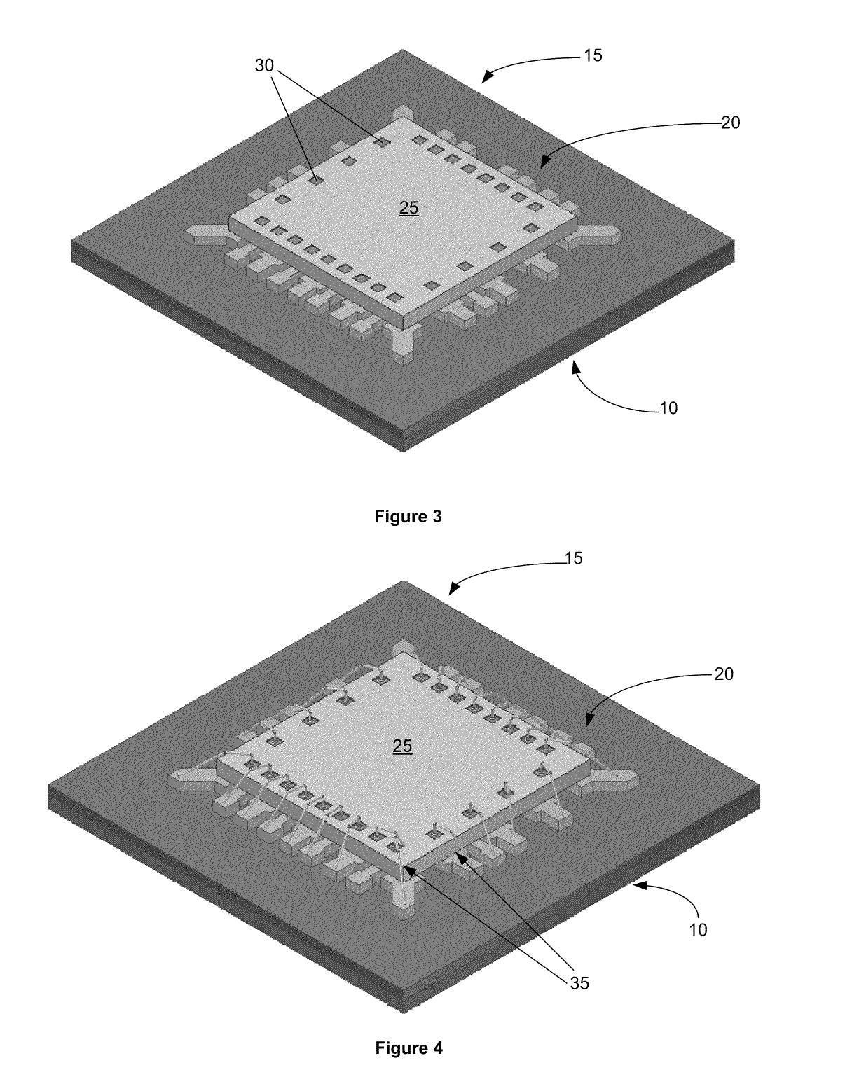

In the embodiments where wirebonds are used, the die 25 can also contain contact pads 30 that are available for electrical connection to the wirebonds. Typically, these contact pads 30 are located in the periphery of the die 25, as illustrated in FIG. 3, and can be made by any process known in the art. The contact pads 30 can be electrically connected to the exposed parts of the interconnect structure 20 in any known manner, including any known wire bonding process. In such instances, the bonding wire 35 may be made of any wire bonding material and can have any suitable size. Some non-limiting examples of wire bonding materials may include Ag, Cu, and combinations thereof other. Where Au is used, the bonding wire may have a diameter from about 12 micrometers to about 50 micrometers.

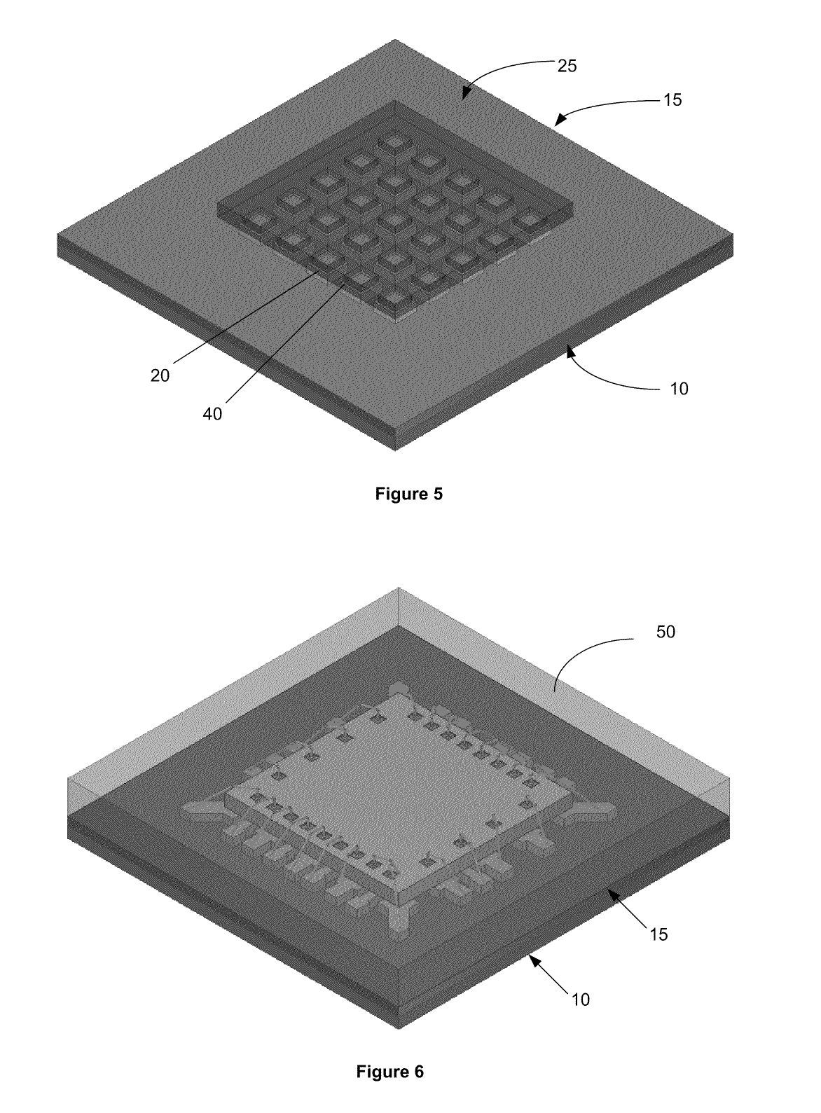

In other embodiments, any known flipchip process can be used to attach the die 25 to the interconnect structure 20. In these embodiments, the IC device(s) on the die can be provided with a bond pad 40 (as shown in FIG. 5) as known in the art. In some embodiments, the bond pads 40 can be provided in those areas that overlay the IC device(s). The bond pads 40 can be formed in the desired location by any process known in the art, including a re-distribution layer method. The bond pads can be made of any known solderable material, including Au, Cu, Ag, Ti, Ni, Sn, W, Ni, or combinations thereof.

In the embodiments where a flipchip process is used, an array of solder bumps, or Cu bumps or pillars, or Au stud bumps can be provided on the bond pads. The bumps can be made of material such as Ag, Sn, Pb, Cu, Sb, Au or combinations thereof. The bumps can be provided on the bond pads through any process known in the art, including electroless plating, ball drop or printing. Then, the die 25 is flipped and placed on the interconnect structure so the bond pad 40 (through the bumps) is attached to the desired locations of the interconnect structure 20, as shown in FIG. 5. The die 25 in FIG. 5 is shown in phantom to better illustrate the connection between the bond pads 40 and the interconnect structure.

The resulting structure in both the wirebond and flipchip embodiments can then be encapsulated in any molding material 50 known in the art, as shown in FIG. 6 (which shows the embodiments that use wirebonding). In FIG. 6, the molding material 50 is shown in phantom to better illustrate the internal components of the semiconductor package. In some embodiments, the molding material 50 can comprise an epoxy molding compound, a thermoset resin, a thermoplastic material, or potting material. In other embodiments, the molding material can comprise an epoxy molding compound. The molding material 50 may be formed using any encapsulation process known in the art, including a transfer molding process.

The process for making the semiconductor package continues when the carrier frame 10 and the tape 15 are removed. In this process, both of these components can be removed by any process that will not damage the structure that remains after their removal. In some embodiments, the removal process can be performed by peeling off the tape and the carrier frame using a tape remover machine with automatic handling system.

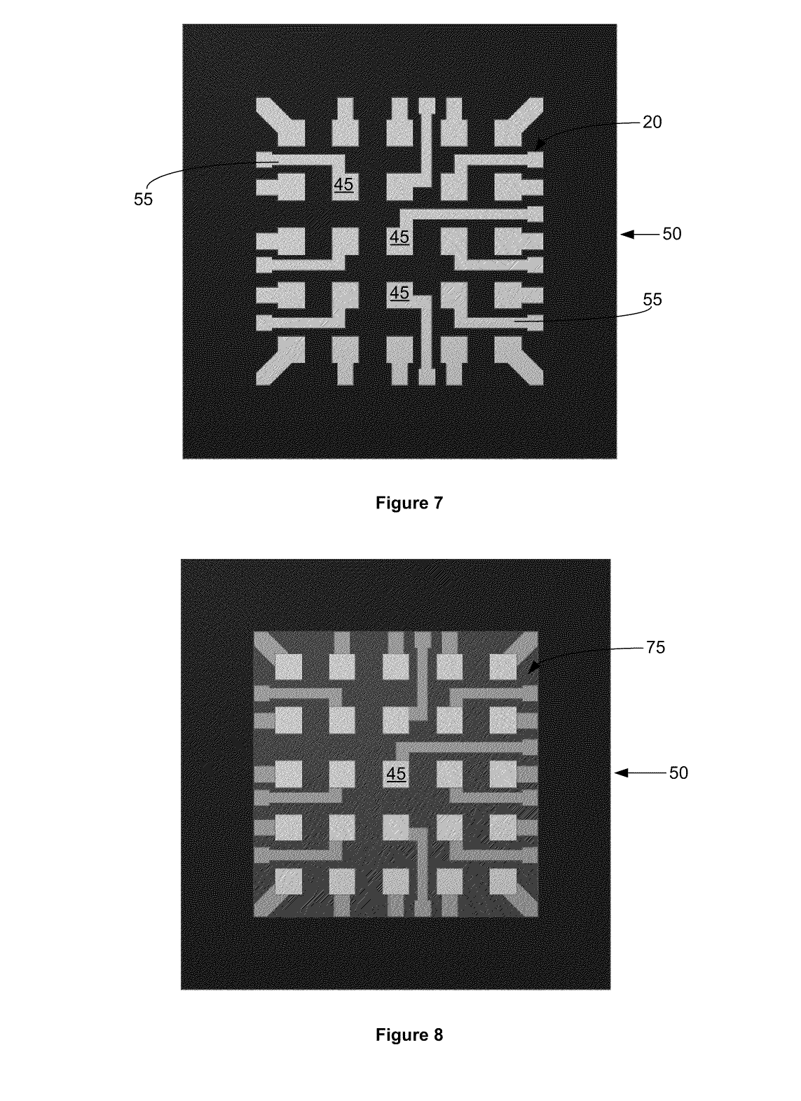

The removal of the carrier frame 10 and the tape 15 leaves the interconnect pattern 20 exposed since the molding material 50 does not encapsulate the bottom surface of the interconnect structure 20. Thus, the bottom surfaces form an array of land pads or lands 45, as shown in FIG. 7 (for the wire bonding embodiments). The interconnect pattern 20 re-routes the electrical signal received from the wirebond (at the exterior of the pattern) and re-routes it via path 55 to the interior of the pattern where the land pads 45 are located. The land pads 45 can have any configuration or layout known in the art consistent with their operation in the semiconductor package. Thus, in the illustrated embodiments, the lands 45 are given a substantially rectangular configuration with a size ranging from about 0.04 to about 0.25 mm². In other embodiments, though, the lands 45 can have a round or other suitable geometrical shape.

A masking process can then be performed, resulting in the structure depicted in FIG. 8. The mask 75 covers the molding material 50 that is located within the interconnect pattern 20 and also covers the re-routing portions 55 of the interconnect pattern 20, thereby leaving only the land pads 45 exposed. The material for the mask 75 can comprise any material that provides a substantially permanent protective coating and can prevent bridging between conductive materials or lands, such as an epoxy liquid, a liquid photoimageable solder mask, or a dry film photoimageable solder mask. The masking process can be performed using any procedure known in the art, such as silkscreen printing-exposed-developed process or vacuum laminate-exposed-developed process. For the flipclip embodiments, the masking process is not required, but is helpful.

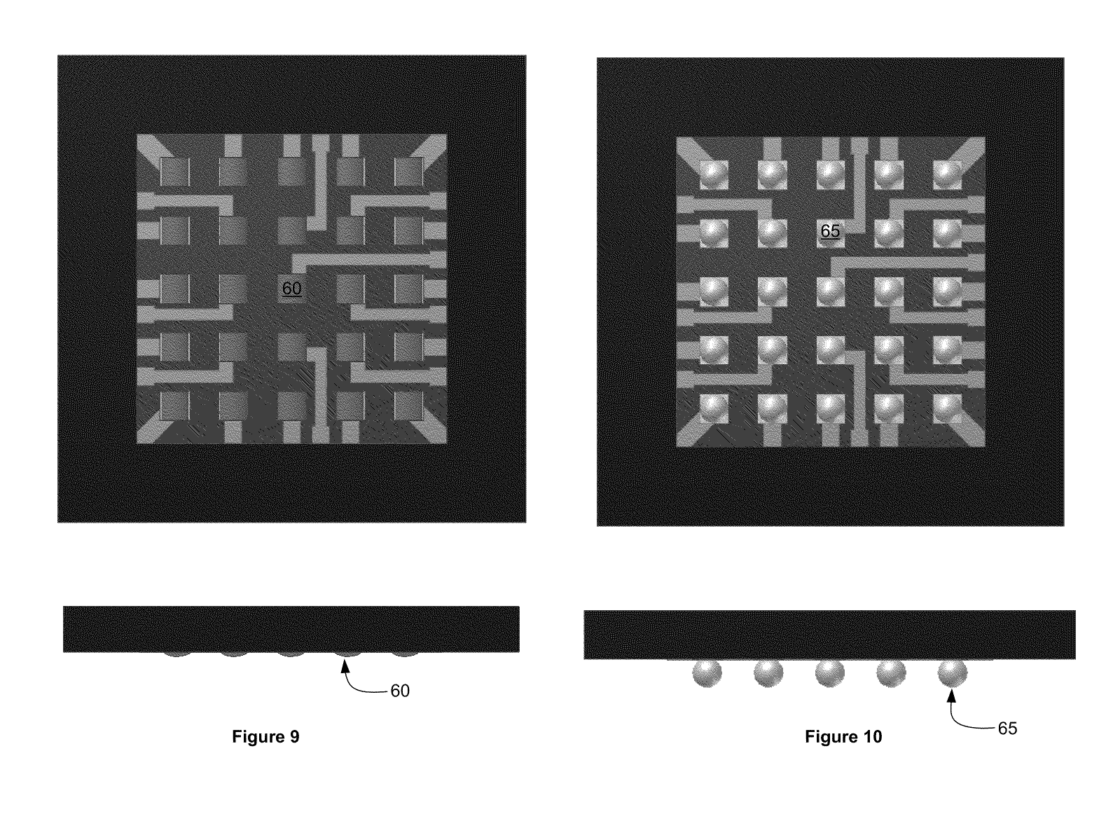

Next, a solder connector is provided on the land pads 45. The solder connector can be used in the connection to the external device (i.e., a printed circuit board) and, therefore, the specific connector can be selected with the specific external device in mind. In some embodiments, such as shown in FIG. 9, the solder connectors comprise solder bumps 60. The solder bumps 60 can comprise any known solder material, such as Sn, Pb, Ag, Cu, Sb, Au, and can be formed using any known bumping process, including a dispensing or screen printing process.

In other embodiments, such as shown in FIG. 10, the solder connectors comprise solder balls 65. The solder balls 65 can comprise any known solder material, such as Sn. Pb, Ag, Cu, Sb, Au, and can be formed using any known process, including a solder ball drop or printing process.

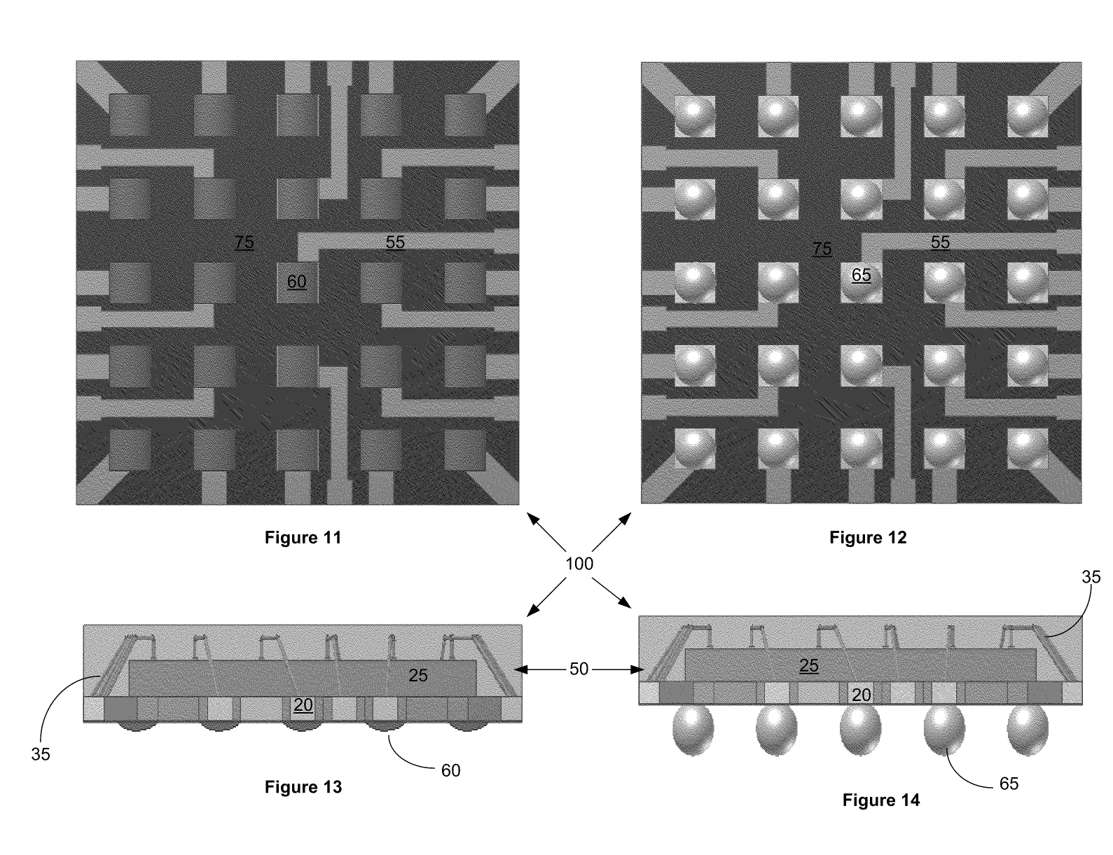

The molded semiconductor package (shown in FIGS. 9 and 10) is then singulated, as shown in FIG. 11 (for the solder bump embodiments) and FIG. 12 (for the solder ball embodiments). The singulation of the molded semiconductor package can be carried out using any process known in the art, including a saw singulation process. Then, the singulated semiconductor packages may be electrically tested, taped, and reeled using any processes known in the art. The semiconductor packages can then be connected to a printed circuit board using the solder connectors and used in any electronic device known in the art such as portable computers, disk drives, USB controllers, portable audio devices, or any other portable/ultraportable electronic devices.

The completed semiconductor package 100 is shown in the side view of FIG. 13 (for the solder bump embodiments) and FIG. 14 (for the solder ball embodiments). The package 100 contains the semiconductor die 25 where the IC device(s) is wirebonded to the exterior of interconnect pattern 20. The interconnect pattern 20 re-routes the electrical signals from the IC device(s) to the interior portion of the patterns were the land pads 45 are located. The interconnect pattern 20 can therefore be routed and customized for a wide variety of land configurations. This allows the semiconductor package 100 to be configured with many different sizes and shapes and used with different die sizes and shapes.

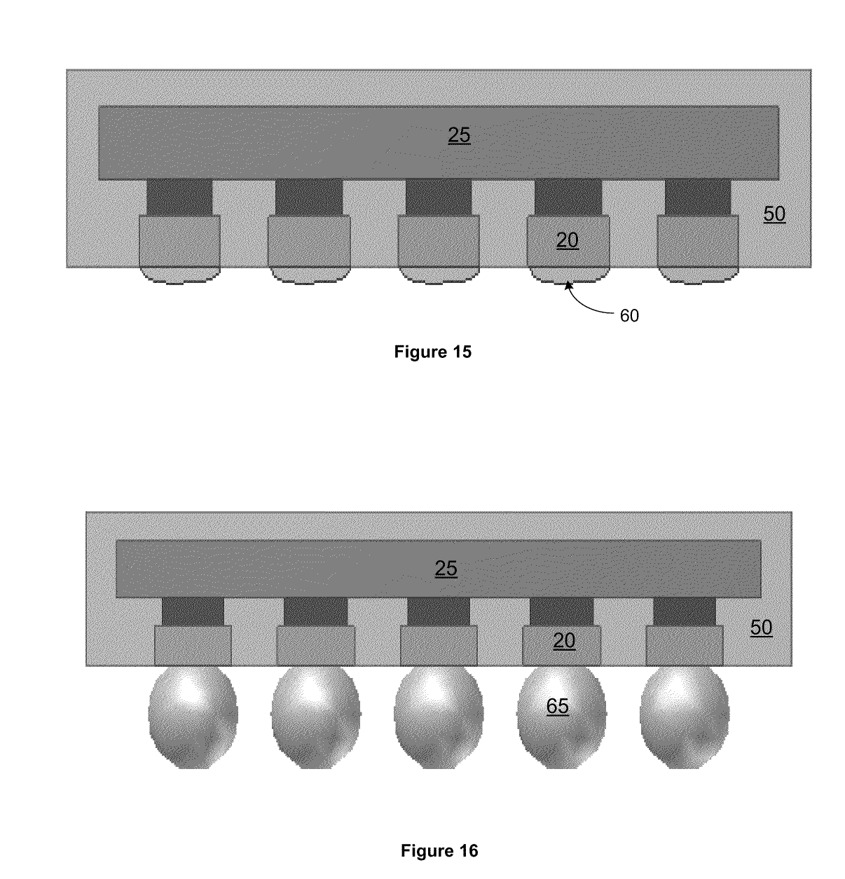

The land pads 45 remain exposed and so that they can be attached to the PCB or other external device using the solder connectors (solder bumps 60 or solder balls 65). For the flipchip embodiments, the IC devices would be located substantially above the land pads, similar to that pattern shown in FIGS. 15-16.

The semiconductor packages formed by these methods have several features. First, the semiconductor packages contain a full array of land pads without using any leads or a leadframe. Second, the semiconductor packages don't require any pre-molding process and yet are flexible enough to use both wirebonding and flipchip processes. Third, the semiconductor packages don't need top etching or any bottom etching processes to form the land pad array and the routing pattern. Both of these latter features provide a high input/output (I/O) capability, flexible routing capability, and a cost effective manufacturing solution.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A leadframe-free semiconductor package, comprising:
an interconnect structure comprising an array of land pads, the interconnect structure formed from and routed using a printable or wirebondable conductive material;
a solderable mask covering the interconnect structure except for the land pads;
a die containing an integrated circuit device connected to the interconnect structure;
a molding material encapsulating the die, the solderable mask, and the interconnect structure except for the land pads; and
solder connectors located on the land pads.

2. The semiconductor package of claim 1, wherein the array of lands comprise terminals for the package.

3. The semiconductor package of claim 1, wherein the integrated circuit device is connected to the interconnect structure using wirebonding.

4. The semiconductor package of claim 1, wherein the integrated circuit device is connected to the interconnect structure using a flipchip process.

5. The semiconductor package of claim 1, wherein the solder connectors comprise solder bumps or solder balls.

6. The semiconductor package of claim 1, wherein the package is a flat package containing no leads and the land pads are located at the bottom of the package.

7. The semiconductor package of claim 1, wherein the interconnect structure is formed without etching.

8. An electronic device containing a leadframe-free semiconductor package comprising:
an interconnect structure comprising an array of land pads, the interconnect structure formed from and routed using a printable or wirebondable conductive material;
a solderable mask covering the interconnect structure except for the land pads;
a die containing an integrated circuit device connected to the interconnect structure;
a molding material encapsulating the die, the solderable mask, and the interconnect structure except for the land pads; and
solder connectors located on the land pads, the solder connectors attached to a printed circuit board.

9. The device of claim 8, wherein the integrated circuit device is connected to the interconnect structure using wirebonding.

10. The device of claim 8, wherein the integrated circuit device is connected to the interconnect structure using a flipchip process.

11. The device of claim 8, wherein the solder connectors comprise solder bumps or solder balls.

12. The device of claim 8, wherein the package is a flat package containing no leads and the land pads are located at the bottom of the package.

13. The device of claim 8, wherein the interconnect structure is formed without etching.

14. A method for making a semiconductor package, comprising:
providing an interconnect structure comprising an array of land pads, the interconnect structure formed from and routed using a printable or wirebondable conductive material;
providing a solderable mask covering the interconnect structure except for the land pads;
providing a die containing an integrated circuit device connected to the interconnect structure;
providing a molding material encapsulating the die, the solderable mask, and the interconnect structure except for the land pads; and
providing solder connectors located on the land pads.

15. The method of claim 14, including connecting the integrated circuit device to the interconnect structure using wirebonding.

16. The method of claim 14, including connecting the integrated circuit device to the interconnect structure using a flipchip process.

17. The method of claim 14, including forming the interconnect structure without using any etching processes.

18. A method for making a semiconductor package, comprising:
providing a re-usable carrier frame;
providing a tape on the carrier frame;
forming an interconnect structure on the tape using a printable or wirebondable conductive material;
attaching a die containing an integrated circuit device to the interconnect structure and electrically connecting the integrated circuit device to the interconnect structure;
encapsulating the interconnect structure and the die with a molding material;
removing the tape and the carrier frame to expose the bottom of the interconnect structure and the molding material; and
forming a solder mask on the molding material and a portion of the interconnect structure to leave a land pad array exposed.

19. The method of claim 18, further comprising forming solder connectors on the land pad array.

20. The method of claim 18, including forming the interconnect structure without using etching.

21. The method of claim 18, including connecting the integrated circuit device to the interconnect structure by wirebonding.

22. The method of claim 21, wherein the interconnect structure re-routes the wirebonding to the land pad array.

23. The method of claim 18, including connecting the integrated circuit device to the interconnect structure by a flipchip process.

24. The method of claim 18, including removing the tape and the carrier frame by peeling off the tape from the interconnect structure and the molding material.

25. The method of claim 24, including re-using the carrier frame in another process for forming a different semiconductor package.
